(19) United States
(12) Patent Application Publication
(10) Pub. No.: US 2025/0275443 A1
(43) Pub. Date: Aug. 28, 2025

(54) DISPLAY DEVICE

(71) Applicant: LG Display Co., Ltd., Seoul (KR)

(72) Inventor: Sunghee KIM, Paju-si (KR)

(73) Assignee: LG Display Co., Ltd., Seoul (KR)

(21) Appl. No.: 19/005,081

(22) Filed: Dec. 30, 2024

(30) Foreign Application Priority Data
Feb. 27, 2024 (KR) 10-2024-0028004

(51) Int. Cl. H10K 59/80; H10K 59/131

(52) U.S. Cl. CPC H10K 59/879; H10K 59/8792; H10K 59/131

(57) ABSTRACT

A display device having an emission area and a circuit area for driving the emission area may include a first overcoat layer having a convex-shaped lens disposed in the emission area, a plurality of micro pillars disposed on the lens, a light-absorbing mold surrounding side surfaces of the plurality of micro pillars and disposed on the first overcoat layer, a second overcoat layer including a plurality of micro lenses corresponding to the plurality of micro pillars, a third overcoat layer disposed on the second overcoat layer and having a flat upper surface, and a light emitting element disposed on the third overcoat layer. Each of the plurality of micro lenses may have a concave shape.

### CROSS REFERENCE TO RELATED APPLICATIONS

The present application claims the benefit of and priority to Korean Patent Application No. 10-2024-0028004, filed Feb. 27, 2024, the entire contents of which are incorporated herein by reference for all purposes.

### BACKGROUND

### 1. Technical Field

The present disclosure relates to a display device, and particularly to, for example, without limitation, a display device in which light extraction efficiency can be increased, a high resolution image can be provided, and a viewing angle can be increased.

### 2 Description of the Related Art

Some examples of flat display devices may include a liquid crystal device, an organic light emitting diode display device, an inorganic light emitting diode display device, a quantum dot display device, and so on.

Light emitted from an organic emission layer of the organic light emitting diode display device is lost in a process of being emitted to the outside by passing through various components of the organic light emitting diode display device. Therefore, to increase the luminance of the organic light emitting diode display device, power consumption increases, which also reduces the lifespan of the organic light emitting diode display device.

Recently, to increase the light extraction efficiency of the organic light emitting diode display device, there is proposed a method of attaching a micro lens array (MLA) to the outside of the organic light emitting diode display device or forming the micro lens array to the overcoat layer in the organic light emitting diode display device.

The description of the related art should not be assumed to be prior art merely because it is mentioned in or associated with this section. The description of the related art includes information that describes one or more aspects of the subject technology, and the description in this section does not limit the invention.

### SUMMARY

However, when a micro lens array is introduced, there is a disadvantage that the resolution of an organic light emitting diode display device is reduced by optical crosstalk between micro lenses, and there is a limit to increasing the viewing angle.

The inventor of the present disclosure has recognized the problems and needs of the related art, including those described above, has performed extensive research and experiments, and has developed a new invention. The inventor of the present disclosure has developed a new optical structure capable of blocking optical crosstalk between the micro lenses and increasing the viewing angle.

One or more example embodiments of the present disclosure are directed to providing a display device in which light extraction efficiency can be increased, a high resolution image can be provided, and a viewing angle can be increased.

The objects of the present disclosure are not limited to the above-described objects, and other objects that are not mentioned will be clearly understood by those skilled in the art from the present disclosure.

A display device including an emission area and a circuit area for driving the emission area according to one embodiment of the present disclosure includes a first overcoat layer having a convex-shaped lens disposed in the emission area, a plurality of micro pillars disposed on the convex-shaped lens, a light-absorbing mold surrounding side surfaces of the plurality of micro pillars and disposed on the first overcoat layer, a second overcoat layer including a plurality of micro lenses corresponding to the plurality of micro pillars, a third overcoat layer disposed on the second overcoat layer and having a flat upper surface, and a light emitting element disposed on the third overcoat layer. Each of the plurality of micro lenses may have a concave shape. Each of the plurality of micro pillars may correspond to a respective one of the plurality of micro lenses, establishing a one-to-one relationship between the plurality of micro pillars and the plurality of micro lenses.

A display device including an emission area and a circuit area according to embodiments of the present disclosure includes a first overcoat layer having a convex-shaped lens disposed in the emission area, a light control layer disposed on the first overcoat layer, a second overcoat layer disposed on the light control layer and including a plurality of micro lenses, a third overcoat layer disposed on the second overcoat layer and having a flat upper surface, and a light emitting element disposed on the third overcoat layer. The plurality of micro lenses may overlap the convex-shaped lens, and each of the plurality of micro lenses may have a concave shape at an upper surface of the second overcoat layer. Here, the light control layer includes a plurality of transmissive parts, and a non-transmissive part near the plurality of transmissive parts. Each of the plurality of transmissive parts may correspond to a respective one of the plurality of micro lenses, establishing a one-to-one relationship between the plurality of transmissive parts and the plurality of micro lenses.

Further detailed matters of example embodiments are included in a detailed description and accompanying drawings.

Additional features, advantages, and aspects of the present disclosure are set forth in part in the description that follows and in part will become apparent from the present disclosure or may be learned by practice of the inventive concepts provided herein. Other features, advantages, and aspects of the present disclosure may be realized and attained by the descriptions provided in the present disclosure, or derivable therefrom, and the claims hereof as well as the drawings. It is intended that all such features, advantages, and aspects be included within this description, be within the scope of the present disclosure, and be protected by the following claims. Nothing in this section should be taken as a limitation on those claims. Further aspects and advantages are discussed below in conjunction with embodiments of the disclosure.

It is to be understood that both the foregoing description and the following description of the present disclosure are examples, and are intended to provide further explanation of the disclosure as claimed.

### BRIEF DESCRIPTION OF THE DRAWINGS

The accompanying drawings, which are included to provide a further understanding of the disclosure, are incorporated in and constitute a part of this disclosure, illustrate aspects and embodiments of the disclosure, and together with the description serve to explain principles and examples of the disclosure.

FIG. 1 is a plan view schematically showing a unit cell of a display device according to one example embodiment of the present disclosure.

FIG. 2 is an example of a cross-sectional view along line 2-2 in FIG. 1.

FIG. 3 is an example of a cross-sectional view along line 3-3 in FIG. 1.

FIGS. 4A and 4B are plan views showing a light control layer according to example embodiments of the present disclosure.

FIGS. 5 to 7 show results of simulating luminance according to a viewing angle while changing a refractive index and a shape of a lens of the display device according to one example embodiment of the present disclosure.

FIG. 8 shows a result of measuring the luminance of the display device according to one example embodiment of the present disclosure according to the viewing angle.

FIGS. 9 and 10 are cross-sectional views showing the display device according to one example embodiment of the present disclosure.

FIG. 11 is a plan view schematically showing the unit cell of the display device according to one example embodiment of the present disclosure.

FIG. 12 is an example of a cross-sectional view along line 12-12 in FIG. 11.

Throughout the drawings and the detailed description, unless otherwise described, the same drawing reference numerals should be understood to refer to the same elements, features, and structures. The sizes, lengths, and thicknesses of layers, regions and elements, and depiction thereof may be exaggerated for clarity, illustration, and/or convenience.

### DETAILED DESCRIPTION

Reference is now made in detail to embodiments of the present disclosure, examples of which may be illustrated in the accompanying drawings. In the following description, when a detailed description of well-known methods, functions, structures or configurations may unnecessarily obscure aspects of the present disclosure, the detailed description thereof may have been omitted for brevity. Further, repetitive descriptions may be omitted for brevity. The progression of processing steps and/or operations described is a non-limiting example.

The sequence of steps and/or operations is not limited to that set forth herein and may be changed to occur in an order that is different from an order described herein, with the exception of steps and/or operations necessarily occurring in a particular order. In one or more examples, two operations in succession may be performed substantially concurrently, or the two operations may be performed in a reverse order or in a different order depending on a function or operation involved.

Unless stated otherwise, like reference numerals may refer to like elements throughout even when they are shown in different drawings. Unless stated otherwise, the same reference numerals may be used to refer to the same or substantially the same elements throughout the specification and the drawings. In one or more aspects, identical elements (or elements with identical names) in different drawings may have the same or substantially the same functions and properties unless stated otherwise. Names of the respective elements used in the following explanations are selected only for convenience and may be thus different from those used in actual products.

Advantages and features of the present disclosure, and implementation methods thereof, are clarified through the embodiments described with reference to the accompanying drawings. The present disclosure may, however, be embodied in different forms and should not be construed as limited to the embodiments set forth herein. Rather, these embodiments are examples and are provided so that this disclosure may be thorough and complete to assist those skilled in the art to understand the inventive concepts without limiting the protected scope of the present disclosure.

Shapes, dimensions (e.g., sizes, lengths, widths, heights, thicknesses, locations, radii, diameters, and areas), proportions, ratios, angles, numbers, the number of elements, and the like disclosed herein, including those illustrated in the drawings, are merely examples, and thus, the present disclosure is not limited to the illustrated details. It is, however, noted that the relative dimensions of the components illustrated in the drawings are part of the present disclosure.

When the term “comprise,” “have,” “include,” “contain,” “constitute,” “made of,” “formed of,” “composed of,” or the like is used with respect to one or more elements (e.g., layers, films, components, parts, regions, areas, portions, steps, operations, and/or the like), one or more other elements may be added unless a term such as “only” or the like is used. The terms used in the present disclosure are merely used in order to describe particular example embodiments, and are not intended to limit the scope of the present disclosure. The terms of a singular form may include plural forms unless the context clearly indicates otherwise. For example, an element may be one or more elements. An element may include a plurality of elements. The word “exemplary” is used to mean serving as an example or illustration. Embodiments are example embodiments.

Aspects are example aspects. In one or more implementations, “embodiments,” “examples,” “aspects,” and the like should not be construed to be preferred or advantageous over other implementations. An embodiment, an example, an example embodiment, an aspect, or the like may refer to one or more embodiments, one or more examples, one or more example embodiments, one or more aspects, or the like, unless stated otherwise. Further, the term “may” encompasses all the meanings of the term “can.”

In one or more aspects, unless explicitly stated otherwise, an element, feature, or corresponding information (e.g., a level, range, dimension, size, or the like) is construed to include an error or tolerance range even where no explicit description of such an error or tolerance range is provided. An error or tolerance range may be caused by various factors (e.g., process factors, internal or external impact, noise, or the like). In interpreting a numerical value, the value is interpreted as including an error range unless explicitly stated otherwise.

When a positional relationship between two elements (e.g., layers, films, components, parts, regions, areas, portions, and/or the like) are described using any of the terms such as “on,” “on a top of,” “upon,” “on top of,” “over,” “under,” “above,” “upper,” “at an upper portion,” “at a upper side,” “below,” “lower,” “at a lower portion,” “at a lower side,” “beneath,” “near,” “close to,” “adjacent to,” “beside,” “next to,” “at or on a side of,” and/or the like indicating a position or location, one or more other elements may be located between the two elements unless a more limiting term, such as “immediate(ly),” “direct(ly),” or “close(ly),” is used. For example, when an element and another element are described using any of the foregoing terms, this description should be construed as including a case in which the elements contact each other directly as well as a case in which one or more additional elements are disposed or interposed therebetween. Furthermore, the spatially relative terms such as the foregoing terms as well as other terms such as “front,” “rear,” “back,” “left,” “right,” “top,” “bottom,” “upper,” “lower,” “downward,” “upward,” “up,” “down,” “column,” “row,” “vertical,” “horizontal,” “diagonal,” and the like refer to an arbitrary frame of reference. For example, these terms may be used for an example understanding of a relative relationship between elements, including any correlation as shown in the drawings. However, embodiments of the disclosure are not limited thereby or thereto. The spatially relative terms are to be understood as terms including different orientations of the elements in use or in operation in addition to the orientation depicted in the drawings or described herein. For example, where a lower element or an element positioned under another element is overturned, then the element may be termed as an upper element or an element positioned above another element. Thus, for example, the term “under” or “beneath” may encompass, in meaning, the term “above” or “over.” An example term “below” or the like, can include all directions, including directions of “below,” “above” and diagonal directions. Likewise, an example term “above,” “on” or the like can include all directions, including directions of “above,” “on,” “below” and diagonal directions.

In describing a temporal relationship, when the temporal order is described as, for example, “after,” “following,” “subsequent,” “next,” “before,” “preceding,” “prior to,” or the like, a case that is not consecutive or not sequential may be included and thus one or more other events may occur therebetween, unless a more limiting term, such as “just,” “immediate ly),” or “direct(ly),” is used.

It is understood that, although the terms “first,” “second,” and the like may be used herein to describe various elements (e.g., layers, films, components, parts, regions, areas, portions, steps, operations, and/or the like), these elements should not be limited by these terms, for example, to any particular order, precedence, or number of elements. These terms are used only to distinguish one element from another. For example, a first element may denote a second element, and, similarly, a second element may denote a first element, without departing from the scope of the present disclosure. Furthermore, the first element, the second element, and the like may be arbitrarily named according to the convenience of those skilled in the art without departing from the scope of the present disclosure. For clarity, the functions or structures of these elements (e.g., the first element, the second element, and the like) are not limited by ordinal numbers or the names in front of the elements. Further, a first element may include one or more first elements. Similarly, a second element or the like may include one or more second elements or the like.

In describing elements of the present disclosure, the terms “first,” “second,” “A,” “B,” “(a),” “(b),” or the like may be used. These terms are intended to identify the corresponding element(s) from the other element(s), and these are not used to define the essence, basis, order, or number of the elements.

For the expression that an element (e.g., layer, film, component, part, region, area, portion, or the like) is “crossing,” “intersecting,” “connected,” “coupled,” “attached,” “adhered,” “combined,” “linked,” or the like another element or to another element, the element can not only be directly crossing, intersecting, connected, coupled, attached, adhered, combined, linked, or the like another element or to another element, but also be indirectly crossing, intersecting, connected, coupled, attached, adhered, combined, linked, or the like another element or to another element with one or more intervening elements disposed or interposed between the elements, unless otherwise specified.

For the expression that an element (e.g., layer, film, component, part, region, area, portion, or the like) “contacts,” “overlaps,” or the like with another element, the element can not only directly contact, overlap, or the like with another element, but also indirectly contact, overlap, or the like with another element with one or more intervening elements disposed or interposed between the elements, unless otherwise specified.

The phrase that an element (e.g., layer, film, component, part, region, area, portion, or the like) is “provided,” “disposed,” “connected,” “coupled,” or the like in, on, with or to another element may be understood, for example, as that at least a portion of the element is provided, disposed, connected, coupled, or the like in, on, with or to at least a portion of another element. The phrase “through” may be understood, for example, to be at least partially through or entirely through. The phrase that an element (e.g., layer, film, component, part, region, area, portion, or the like) “contacts,” “overlaps,” or the like with another element may be understood, for example, as that at least a portion of the element contacts, overlaps, or the like with a least a portion of another element.

The terms such as a “line” or “direction” should not be interpreted only based on a geometrical relationship in which the respective lines or directions are parallel, perpendicular, diagonal, or slanted with respect to each other, and may be meant as lines or directions having wider directivities within the range within which the components of the present disclosure may operate functionally. For example, the terms “first direction,” “second direction,” “X-axis direction,” “Y-axis direction,” and the like should not be interpreted only based on a geometrical relationship in which the respective directions are parallel, perpendicular, diagonal, or slanted with respect to each other, and may be meant as directions having wider directivities within the range within which the components of the present disclosure may operate functionally.

The term “at least one” should be understood as including any and all combinations of one or more of the associated listed items. For example, each of the phrases “at least one of a first item, a second item, or a third item” and “at least one of a first item, a second item, and a third item” may represent (i) a combination of items provided by two or more of the first item, the second item, and the third item or (ii) only one of the first item, the second item, or the third item.

The expression of a first element, a second elements “and/or” a third element should be understood as one of the first, second and third elements or as any or all combinations of the first, second and third elements. By way of example, A, B and/or C may refer to only A; only B; only C; any of A, B, and C (e.g., A, B, or C); some combination of A, B, and C (e.g., A and B; A and C; or B and C); or all of A, B, and C. Furthermore, an expression “A/B” may be understood as A and/or B. For example, an expression “A/B” may refer to only A; only B; A or B; or A and B.

In one or more aspects, the terms “between” and “among” may be used interchangeably simply for convenience unless stated otherwise. For example, an expression “between a plurality of elements” may be understood as among a plurality of elements. In another example, an expression “among a plurality of elements” may be understood as between a plurality of elements. In one or more examples, the number of elements may be two. In one or more examples, the number of elements may be more than two. Furthermore, when an element (e.g., layer, film, component, part, region, area, portion, or the like) is referred to as being “between” at least two elements, the element may be the only element between the at least two elements, or one or more intervening elements may also be present.

In one or more aspects, the phrases “each other” and “one another” may be used interchangeably simply for convenience unless stated otherwise. For example, an expression “different from each other” may be understood as being different from one another. In another example, an expression “different from one another” may be understood as being different from each other. In one or more examples, the number of elements involved in the foregoing expression may be two. In one or more examples, the number of elements involved in the foregoing expression may be more than two.

In one or more aspects, the phrases “one or more among” and “one or more of” may be used interchangeably simply for convenience unless stated otherwise.

The term “or” means “inclusive or” rather than “exclusive or.” That is, unless otherwise stated or clear from the context, the expression that “x uses a or b” means any one of natural inclusive permutations. For example, “a or b” may mean “a,” “b,” or “a and b.” For example, “a, b or c” may mean “a,” “b,” “c,” “a and b,” “b and c,” “a and c,” or “a, b and c.”

Features of various embodiments of the present disclosure may be partially or entirely coupled to or combined with each other, may be technically associated with each other, and may be variously operated, linked or driven together in various ways. Embodiments of the present disclosure may be implemented or carried out independently of each other or may be implemented or carried out together in a co-dependent or related relationship. In one or more aspects, the components of each apparatus and device according to various embodiments of the present disclosure are operatively coupled and configured.

Unless otherwise defined, the terms (including technical and scientific terms) used herein have the same meaning as commonly understood by one of ordinary skill in the art to which example embodiments belong. It is further understood that terms, such as those defined in commonly used dictionaries, should be interpreted as having a meaning that is, for example, consistent with their meaning in the context of the relevant art and should not be interpreted in an idealized or overly formal sense unless expressly defined otherwise herein.

The terms used herein have been selected as being general in the related technical field; however, there may be other terms depending on the development and/or change of technology, convention, preference of technicians, and so on. Therefore, the terms used herein should not be understood as limiting technical ideas, but should be understood as examples of the terms for describing example embodiments.

Further, in a specific case, a term may be arbitrarily selected by an applicant, and in this case, the detailed meaning thereof is described herein. Therefore, the terms used herein should be understood based on not only the name of the terms, but also the meaning of the terms and the content hereof.

In the following description, various example embodiments of the present disclosure are described in more detail with reference to the accompanying drawings. With respect to reference numerals to elements of each of the drawings, the same elements may be illustrated in other drawings, and like reference numerals may refer to like elements unless stated otherwise.

The same or similar elements may be denoted by the same reference numerals even though they are depicted in different drawings. In addition, for convenience of description, a scale, dimension, size, and thickness of each of the elements illustrated in the accompanying drawings may be different from an actual scale, dimension, size, and thickness, and thus, embodiments of the present disclosure are not limited to a scale, dimension, size, and thickness illustrated in the drawings.

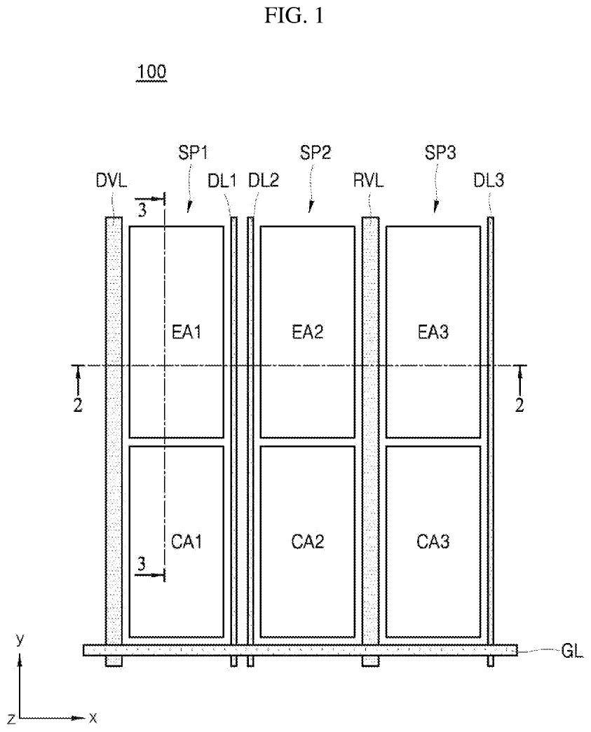

FIG. 1 is a plan view schematically showing the unit pixel of the display device according to one example embodiment of the present disclosure.

Referring to FIG. 1, a display device 100 according to one example embodiment of the present disclosure may include a pixel including a first sub-pixel SP1, a second sub-pixel SP2 adjacent to the first sub-pixel SP1, and a third sub-pixel SP3 adjacent to the second sub-pixel SP2. In the display device 100 according to one example embodiment of the present disclosure, the same pixels may be repeatedly disposed.

The first sub-pixel SP1 may include a first emission area EAl and a first circuit area CA1 for driving the first emission area. The second sub-pixel SP2 may include a second emission area EA2 and a second circuit area CA2 for driving the second emission area. The third sub-pixel SP3 may include a third emission area EA3 and a third circuit area CA3 for driving the third emission area. The first to third emission areas EA1, EA2, and EA3 and the first to third circuit areas CA1, CA2, and CA3 may be areas of the substrate.

A light emitting element may be disposed in the first to third emission areas EA1, EA2, and EA3, and a thin film transistor and a capacitor may be disposed in the first to third circuit areas CA1, CA2, and CA3. For example, the light emitting element may emit white light.

For example, the first sub-pixel SP1 may be a red sub-pixel, the second sub-pixel SP2 may be a green sub-pixel, and the third sub-pixel SP3 may be a blue sub-pixel.

A display device 100 according to one example embodiment of the present disclosure may include first to third data lines DL1, DL2, and DL3 to which data voltages are supplied by a data driver, a driving voltage line DVL to which a driving voltage is supplied, a reference voltage line RVL to which a reference voltage is supplied, and a gate line GL which intersects the first to third data lines DL1, DL2, and DL3 and to which a gate voltage is supplied by a gate driver. The driving voltage line DVL and the reference voltage line RVL may also intersect the gate line GL.

For example, the first to third data lines DL1, DL2, and DL3, the driving voltage line DVL, and the reference voltage line RVL may extend in the Y-axis direction, and the gate line GL may extend in the X-axis direction.

For example, the first sub-pixel SP1 may be disposed between the driving voltage line DVL and the first data line DL1, and the second sub-pixel SP2 may be disposed between the second data line DL2 and the reference voltage line RVL. For example, the third sub-pixel SP3 may be disposed between the reference voltage line RVL and the third data line DL3.

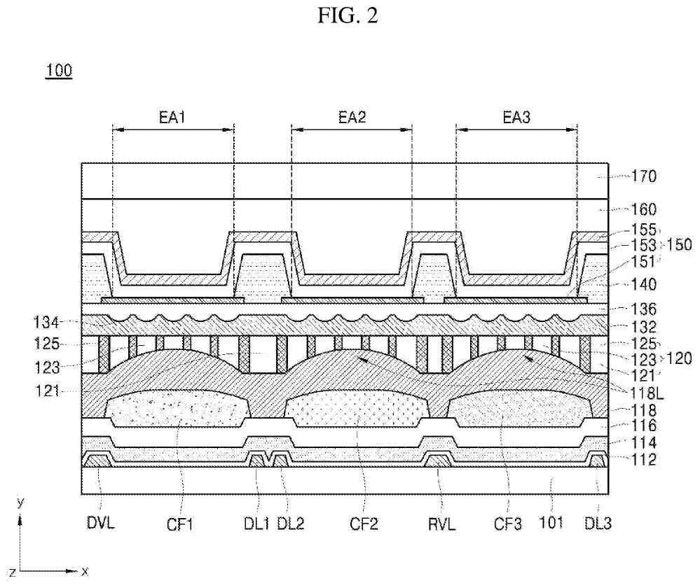

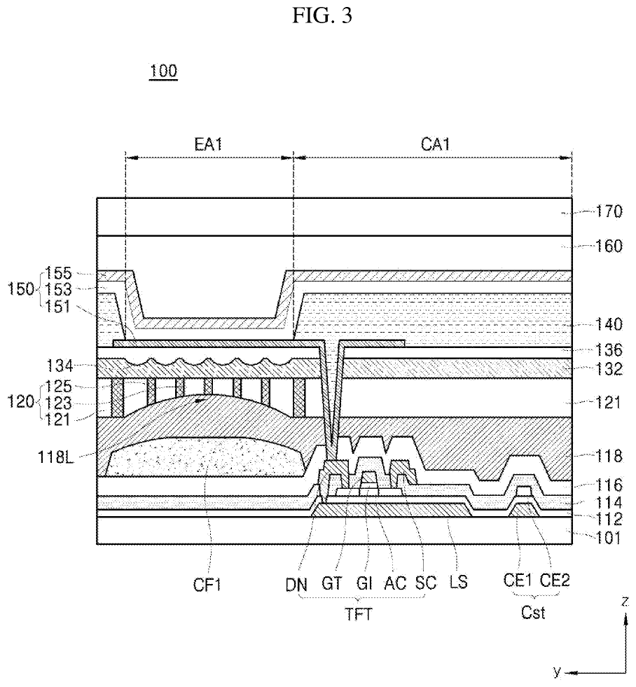

FIG. 2 is an example of a cross-sectional view along line 2-2 in FIG. 1. FIG. 3 is an example of a cross-sectional view along line 3-3 in FIG. 1.

Referring to FIG. 2, the driving voltage line DVL, the first data line DL1, the second data line DL2, the reference voltage line RVL, and the third data line DL3 may be disposed to be spaced apart from each other on a substrate 101.

A buffer layer 112 may cover the driving voltage line DVL, the first data line DL1, the second data line DL2, the reference voltage line RVL, and the third data line DL3 and may be disposed on a substrate 101.

An interlayer insulating layer 114 may be disposed on the buffer layer 112. In addition, a passivation layer 116 may be disposed on the interlayer insulating layer 114.

A first color filter CF1, a second color filter CF2, and a third color filter CF3 may be disposed on the passivation layer 116. The first color filter CF1 may be disposed in the first emission area EA1. The second color filter CF2 may be disposed in the second emission area EA2. The third color filter CF3 may be disposed in the third emission area EA3. For example, the first color filter CF1 may be a red color filter, the second color filter CF2 may be a green color filter, and the third color filter CF3 may be a blue color filter.

A first overcoat layer 118 may cover the first color filter CF1, the second color filter CF2, and the third color filter CF3 and may be disposed on the passivation layer 116. The first overcoat layer 118 may have convex-shaped lenses 118L disposed in the first to third emission areas EA1, EA2, and EA3. The lenses 118L may be disposed on the first to third color filters CF1, CF2, and CF3. The lenses 118L may be formed on an upper surface of the first overcoat layer 118 to overlap the first to third color filters CF1, CF2, and CF3. The lenses 118L may be a portion of the first overcoat layer 118. In one example embodiment, the lenses 118L may be formed separately from the first overcoat layer 118 on the upper surface of the first overcoat layer 118.

The first overcoat layer 118 and the lens 118L may be made of an insulating material having a first refractive index. For example, the first overcoat layer 118 and the lens 118L may be made of a material having a refractive index of 1.3 to 1.45.

With respect to a cross section of the lens 118L along a direction in which the gate line GL extends, an aspect ratio of the lens 118L may be in the range of 0.2 or more and 1.5 or less. The aspect ratio of the lens 118L may be in the range of 0.2 or more and 1.0 or less. Here, the aspect ratio of the lens 118L may be defined as a ratio of a height of the lens to a size of a bottom surface of the lens. When the aspect ratio of the lens 118L is smaller than 0.2, the effect of increasing a luminance viewing angle can be very small, and when the aspect ratio exceeds 1.5, the effect of increasing the luminance viewing angle can be rather reduced.

At least one lens 118L having a predetermined aspect ratio may be disposed in each emission area. Although it is shown in FIG. 2 that one lens 118L is disposed in each emission area, the present disclosure is not limited thereto. For example, a plurality of lenses 118L having the predetermined aspect ratio may be disposed in each emission area.

A light control layer 120 may be disposed on the first overcoat layer 118. The light control layer 120 may include a plurality of micro pillars 123 disposed on each lens 118L, a light-absorbing mold 125 surrounding side surfaces of the plurality of micro pillars 123, and an insulating layer 121 surrounding side surfaces of the light-absorbing mold 125. The insulating layer 121 may be disposed on the remaining area of the upper surface of the first overcoat layer 118 excluding an area in which the plurality of micro pillars 123 and the light-absorbing mold 125 are disposed. The plurality of micro pillars 123 may be disposed in the first to third emission areas

EA1, EA2, and EA3. A width of the light-absorbing mold 125 disposed outside the first to third emission areas EA1, EA2, and EA3 may be greater than a width of the light-absorbing mold 125 disposed in the first to third emission areas EA1, EA2, and EA3.

Lower surfaces of the plurality of micro pillars 123 may be in contact with the lens 118L, and upper surfaces of the plurality of micro pillars 123 may be flat.

A lower surface of the light-absorbing mold 125 may be in contact with the lens 118L, and an upper surface of the light-absorbing mold 125 may be flat. In one example embodiment, the upper surface of the light-absorbing mold 125 may be convex or concave.

The plurality of micro pillars 123 may be areas in which light emitted from the light emitting element 150 to be described in further detail below may be transmitted, and the light-absorbing mold 125 may be an area in which light emitted from the light emitting element 150 may be absorbed. The light-absorbing mold 125 may include a polymer capable of absorbing light. The light-absorbing mold 125 may include, for example, an ink or a photoresist having a black color. The micro pillar 123 may be a transmissive part, and the light-absorbing mold 125 may be a non-transmissive part.

The plurality of micro pillars 123 and the insulating layer 121 may be made of an insulating material having a second refractive index. The second refractive indexes of the plurality of micro pillars 123 may be higher than the first refractive index of the lens 118L. The first refractive index of the lens 118L may be lower than the second refractive indexes of the plurality of micro pillars 123. For example, the plurality of micro pillars 123 may be made of a material having a refractive index of 1.55 to 1.65.

A second overcoat layer 132 including a plurality of micro lenses 134 having a concave shape may be disposed on the light control layer 120. The plurality of micro lenses 134 may be disposed in the first to third emission areas EA1, EA2, and EA3. The second overcoat layer 132 may be made of an insulating material having a third refractive index. The third refractive index of the second overcoat layer 132 may be lower than the second refractive indexes of the plurality of micro pillars 123. The second refractive indexes of the plurality of micro pillars 123 may be higher than the third refractive index of the second overcoat layer 132. For example, the second overcoat layer 132 may be made of a material having a refractive index of 1.45 to 1.6.

A third overcoat layer 136 may be disposed on the second overcoat layer 132. The third overcoat layer 136 may cover the plurality of micro lenses 134 of the second overcoat layer 132 and have a flat upper surface. The third overcoat layer 136 may be made of an insulating material having a fourth refractive index. The fourth refractive index of the third overcoat layer 136 may be higher than the third refractive index of the second overcoat layer 132. The third refractive index of the second overcoat layer 132 may be lower than the fourth refractive index of the third overcoat layer 136. For example, the third overcoat layer 136 may be made of a material having a refractive index of 1.6 to 1.7.

The plurality of micro lenses 134 may be disposed to correspond one-to-one to the plurality of micro pillars 123.

A diameter or size of each of the plurality of micro pillars 123 may be smaller than a diameter or size of each of the plurality of micro lenses 134. A convex portion around the plurality of micro lenses 134 may overlap the light-absorbing mold 125.

One micro pillar 123 and one micro lens 134 corresponding thereto may form one micro channel through which light emitted from the light emitting element 150 may be transmitted.

The light emitting elements 150 may be disposed on the third overcoat layer 136. The first electrodes 151 spaced apart from each other may be disposed on the third overcoat layer 136. One first electrode 151 may be disposed in each sub-pixel. The first electrodes 151 may be pixel electrodes or anode electrodes. The first electrodes 151 may include a transparent conductive material.

The bank layer 140 may be disposed on the third overcoat layer 136. The bank layer 140 may include openings that expose portions of the first electrodes 151. The bank layer 140 may cover edge portions of the first electrodes 151. The first to third emission areas EA1, EA2, and EA3 may be defined by portions of the first electrodes 151 not covered or obscured by the bank layer 140.

An organic light emitting layer 153 may be disposed on the first electrodes 151. The organic light emitting layer 153 may also be disposed on the bank layer 140. The organic light emitting layer 153 may emit white light. In one or more examples, an emission layer may be the organic light emitting layer 153.

A second electrode 155 may be disposed on the organic light emitting layer 153. The second electrode 155 may be a common electrode or a cathode electrode. The second electrode 155 may include a reflective conductive material.

The first electrode 151, the organic light emitting layer 153, and the second electrode 155 may constitute the light emitting element 150.

An encapsulation layer 160 may be disposed on the second electrode 155, and a protective layer 170 may be disposed on the encapsulation layer 160. The encapsulation layer 160 may include at least one inorganic insulating material or at least one organic insulating material. The encapsulation layer 160 may be a seal layer or an adhesive layer. The protective layer 170 may include an inorganic insulating material, an organic insulating material, or a metal material.

Referring to FIG. 3, a light shield layer LS and a lower capacitor electrode CE1 may be disposed on the substrate 101. The light shield layer LS and the lower capacitor electrode CE1 may be disposed in the first circuit area CA1. The light shield layer LS and the lower capacitor electrode CE1 may be made of the same material as the driving voltage line DVL, the first data line DL1, the second data line DL2, the reference voltage line RVL, and the third data line DL3.

The light shielding layer LS can prevent external light from entering into a thin film transistor TFT to be described below.

The buffer layer 112 may cover the light shielding layer LS and the lower capacitor electrode CE1 and may be disposed on the substrate 101.

An active pattern AC and an upper capacitor electrode CE2 may be disposed on the buffer layer 112. The lower capacitor electrode CE1 and the upper capacitor electrode CE2 may constitute a capacitor Cst.

A gate electrode GT may be disposed on the active pattern AC. A gate insulating layer GI may be disposed between the gate electrode GT and the active pattern AC. The gate line GL (see FIG. 1) may be disposed coplanarly with the gate electrode GT. The gate electrode GT may be disposed under the first overcoat layer, and the gate line GL may be disposed under the first overcoat layer. The gate electrode GT may be connected to the gate line GL.

A passivation layer 114 covering the active pattern AC and the gate electrode GT may be disposed on the buffer layer 112.

A source electrode SC and a drain electrode DN may be respectively connected to source and drain areas of the active pattern AC by passing through the interlayer insulating layer 114.

The active pattern AC, the gate insulating layer GI, the gate electrode GT, the source electrode SC, and the drain electrode DN may form the thin film transistor TFT.

The passivation layer 116 covering the source electrode SC and the drain electrode DN of the thin film transistor TFT may be disposed on the interlayer insulating layer 114.

The first color filter CF1 may be disposed on the passivation layer 116. The first color filter CF1 may be disposed in the first emission area EA1.

The first overcoat layer 118 covering the first color filter CF1 may be disposed on the passivation layer 116.

The first overcoat layer 118 may have a convex-shaped lens 118L disposed in the first emission area EA1 on an upper surface thereof. The lens 118L may overlap the first color filter CF1. The lenses 118L may be disposed on the first color filter CF1.

The light control layer 120 may be disposed on the first overcoat layer 118. The light control layer 120 may include the plurality of micro pillars 123 disposed on the lens 118L, the light-absorbing mold 125 surrounding the side surfaces of the plurality of micro pillars 123, and the insulating layer 121 surrounding the side surfaces of the light-absorbing mold 125. The insulating layer 121 may be disposed on the remaining area of the upper surface of the first overcoat layer 118 excluding an area in which the plurality of micro pillars 123 and the light-absorbing mold 125 are disposed. The insulating layer 121 may be disposed in the first circuit area CA1.

The second overcoat layer 132 including the plurality of micro lenses 134 having a concave shape on an upper surface thereof may be disposed on the light control layer 120.

The third overcoat layer 136 may be disposed on the second overcoat layer 132. The third overcoat layer 136 may cover the plurality of micro lenses 134 of the second overcoat layer 132 and have a flat upper surface.

The plurality of micro lenses 134 may be disposed to correspond one-to-one to the plurality of micro pillars 123. The diameter or size of each of the plurality of micro pillars 123 may be smaller than the diameter or size of each of the plurality of micro lenses 134.

The light emitting elements 150 may be disposed on the third overcoat layer 136. The first electrode 151 may be disposed on the third overcoat layer 136. The first electrode 151 may be connected to the thin film transistor TFT by passing through the third overcoat layer 136, the second overcoat layer 132, the insulating layer 121, the first overcoat layer 118, and the passivation layer 116 in the first circuit area CA1.

Although FIG. 3 show that the first electrode 151 is connected to the drain electrode DN of the thin film transistor TFT, the present disclosure is not limited thereto. In one example embodiment, the first electrode 151 may be connected to the source electrode SC of the thin film transistor TFT.

The bank layer 140 may be disposed on the third overcoat layer 136. The bank layer 140 may cover the edge portions of the first electrode 151.

The organic light emitting layer 153 may be disposed on the first electrodes 151. The organic light emitting layer 153 may also be disposed on the bank layer 140.

The second electrode 155 may be disposed on the organic light emitting layer 153.

The encapsulation layer 160 may be disposed on the second electrode 155, and the protective layer 170 may be disposed on the encapsulation layer 160.

According to one example embodiment of the present disclosure, it is possible to increase the light extraction efficiency of the display device 100 by arranging the micro lenses under the light emitting element.

In addition, the micro channels capable of blocking optical crosstalk can be formed by arranging the black light-absorbing mold for absorbing light between the micro pillars corresponding one-to-one under the micro lenses. Therefore, it is possible to increase the contrast ratio and resolution of the display device 100.

In addition, it is possible to increase the luminance viewing angle of the display device 100 by arranging the lens having a low refractive index under the micro pillars.

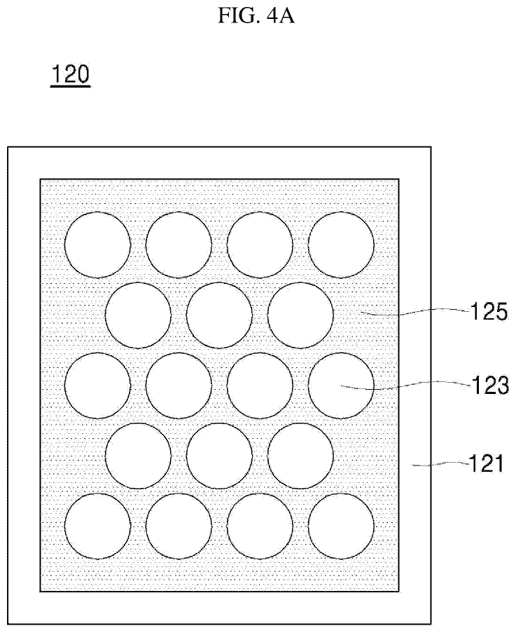

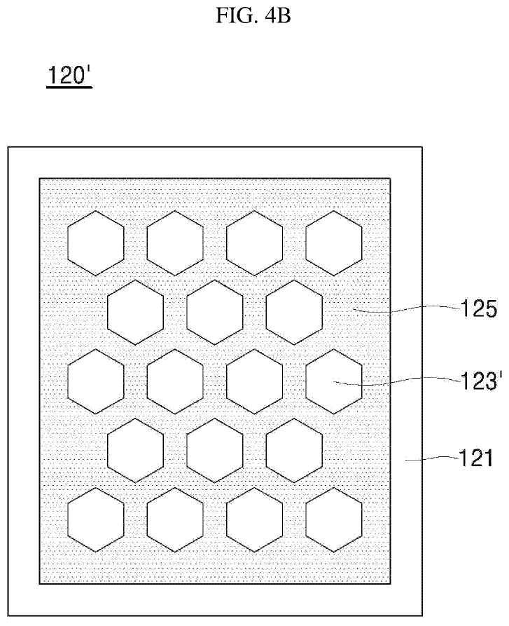

FIGS. 4A and 4B are plan views showing a light control layer according to one example embodiment of the present disclosure.

Referring to FIG. 4A, the light control layer 120 may include the plurality of micro pillars 123 having a circular transverse cross section, the light-absorbing mold 125 surrounding the side surfaces of the plurality of micro pillars 123 and absorbing light, and the insulating layer 121 surrounding the side surfaces of the light-absorbing mold 125. The micro pillars 123 may have a cylindrical shape.

Referring to FIG. 4B, a light control layer 120′ may include a plurality of micro pillars 123′ having a polygonal, for example, hexagonal transverse cross section, the light-absorbing mold 125 surrounding the side surfaces of the plurality of micro pillars 123′, and the insulating layer 121 surrounding the side surfaces of the light-absorbing mold 125. The micro pillars 123′ may have a polygonal pillar shape, for example, a hexagonal pillar shape.

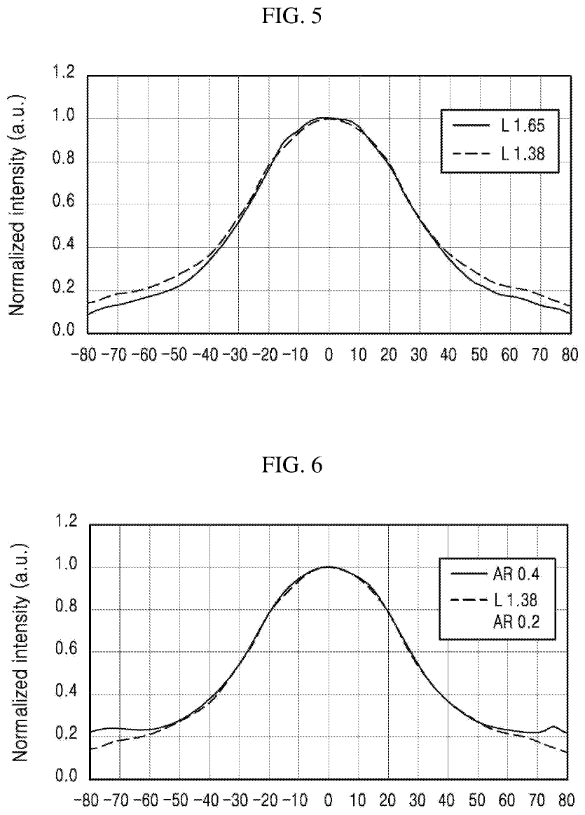

FIGS. 5 to 7 show results of simulating luminance according to a viewing angle while changing a refractive index and a shape of a lens of the display device according to one example embodiment of the present disclosure. To check a change in luminance viewing angle according to the refractive index and shape of the lens, a simplified structure in which the components disposed on the lens were omitted was used in simulations of FIGS. 5 to 7.

FIG. 5 shows the simulation result for a case where the aspect ratio of the lens is 0.2 and the refractive index of the lens is 1.65 and 1.38. Referring to FIG. 5, it can be seen that the case where the refractive index of the lens is 1.38 (the case of being smaller than the refractive index of the upper layer) has a higher luminance than the case where the refractive index of the lens is 1.65 (case of being the same as or similar to the refractive index of the upper layer) at a viewing angle of 35 degrees or more.

FIG. 6 shows the simulation result for cases where the refractive index of the lens is 1.38 and the aspect ratio of the lens is 0.2 and 0.4. Referring to FIG. 6, it can be seen that the case where the aspect ratio is 0.4 has a higher luminance than the case where the aspect ratio is 0.2 at a viewing angle of 55 degrees or more.

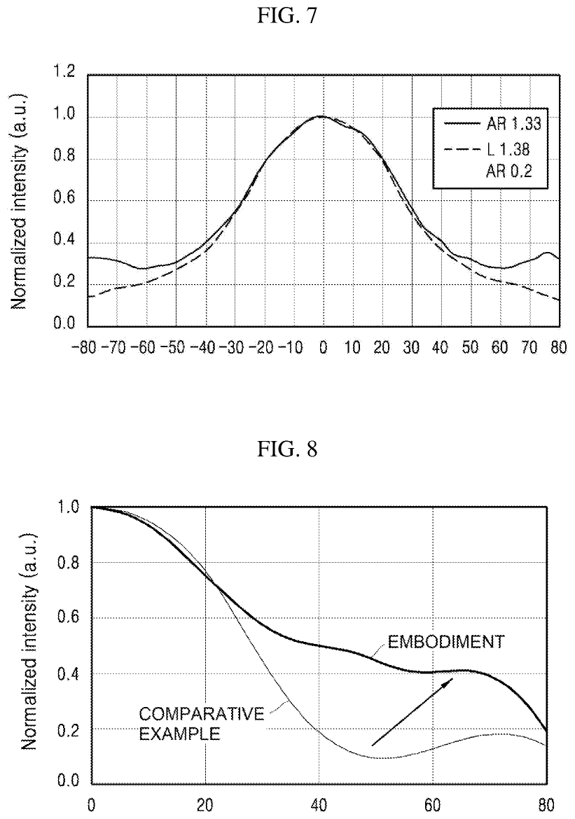

FIG. 7 shows the simulation result for cases where the refractive index of the lens is 1.38 and the aspect ratio of the lens is 0.2 and 1.33. Referring to FIG. 7, it can be seen that the case where the aspect ratio is 1.33 has a higher luminance than the case where the aspect ratio is 0.2 at a viewing angle of 30 degrees or more.

According to the simulation results of FIGS. 5 to 7, it can be seen that as the refractive index of the lens is low and the aspect ratio of the lens is high, the viewing angle increases.

FIG. 8 shows the result of measuring the luminance of the display device according to one example embodiment of the present disclosure according to the viewing angle. The lens having the low refractive index (n=1.38) included in the display device according to one example embodiment of the present disclosure has an aspect ratio of 0.4.

Referring to FIG. 8, it can be seen that the luminance of the display device according to the example embodiment is higher than that of Comparative Example not including the lens having the low refractive index at a viewing angle of 20 degrees or more. That is, it can be seen that the luminance viewing angle of the display device according to the example embodiment is wider than the luminance viewing angle of the display device according to Comparative Example.

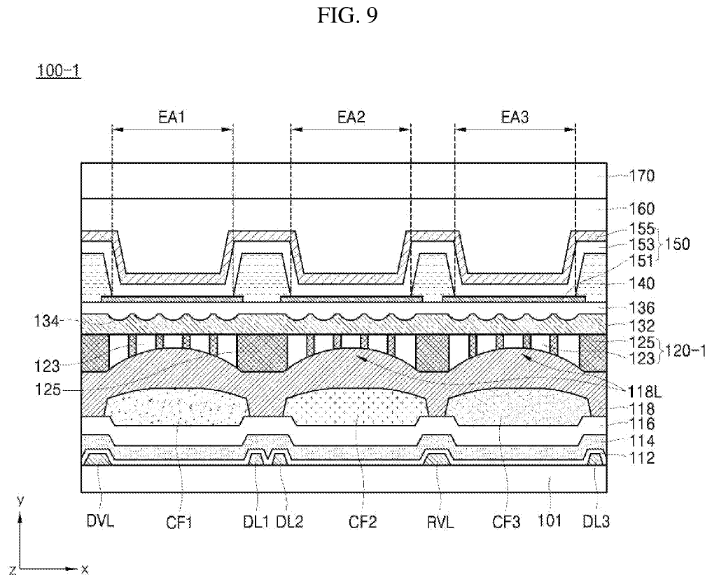

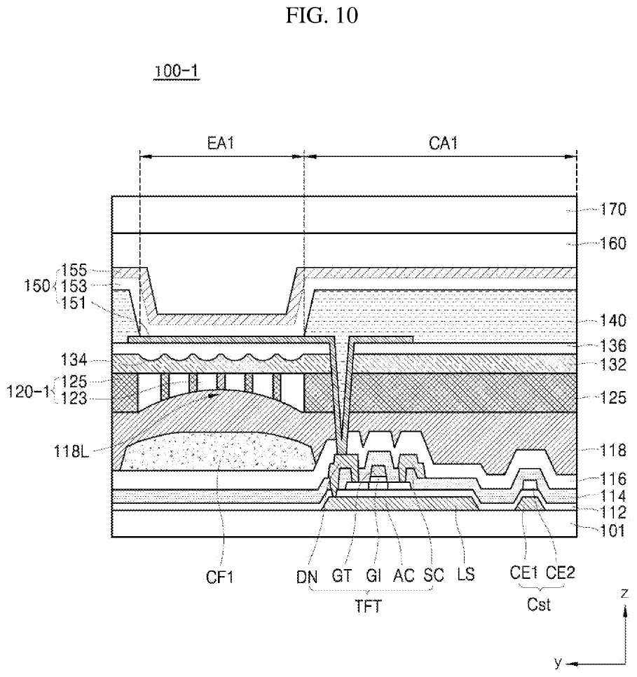

FIGS. 9 and 10 are cross-sectional views showing a display device 100-1 according to one example embodiment of the present disclosure.

The display device 100-1 according to one example embodiment of the present disclosure shown in FIGS. 9 and 10 is the same as the display device 100, except that a light control layer 120-1 instead of the light control layer 120 is disposed on the first overcoat layer 118. Thus, repetitive descriptions may be omitted for brevity.

Referring to FIGS. 9 and 10, the light control layer 120-1 may be disposed on the first overcoat layer 118. The light control layer 120-1 may include the plurality of micro pillars 123 disposed on the lens 118L and the light-absorbing mold 125 surrounding the side surfaces of the plurality of micro pillars 123.

The light-absorbing mold 125 may extend to the circuit areas CA1, CA2, and CA3 and may be disposed on the entireties of the circuit areas CA1, CA2, and CA3. The light-absorbing mold 125 may be disposed on the remaining area of the upper surface of the first overcoat layer 118 excluding the area in which the plurality of micro pillars 123 are disposed.

The light emitting elements 150 may be disposed on the third overcoat layer 136. The first electrode 151 may be disposed on the third overcoat layer 136. The first electrode 151 may be connected to the thin film transistor TFT by passing through the third overcoat layer 136, the second overcoat layer 132, the light-absorbing mold 125, the first overcoat layer 118, and the passivation layer 116 in the first circuit area CA1.

According to one example embodiment of the present disclosure, it is possible to increase the light extraction efficiency of the display device 100-1 by arranging the micro lenses under the light emitting element.

In addition, the micro channels capable of blocking optical crosstalk can be formed by arranging the light-absorbing mold for absorbing light between the micro pillars corresponding one-to-one under the micro lenses. Therefore, it is possible to increase the resolution of the display device 100-1.

In addition, it is possible to further increase the contrast ratio of the display device 100-1 by arranging the black light-absorbing mold in the entirety of the remaining area excluding the micro pillars.

In addition, it is possible to increase the luminance viewing angle of the display device 100-1 by arranging the lens having the low refractive index under the micro pillars.

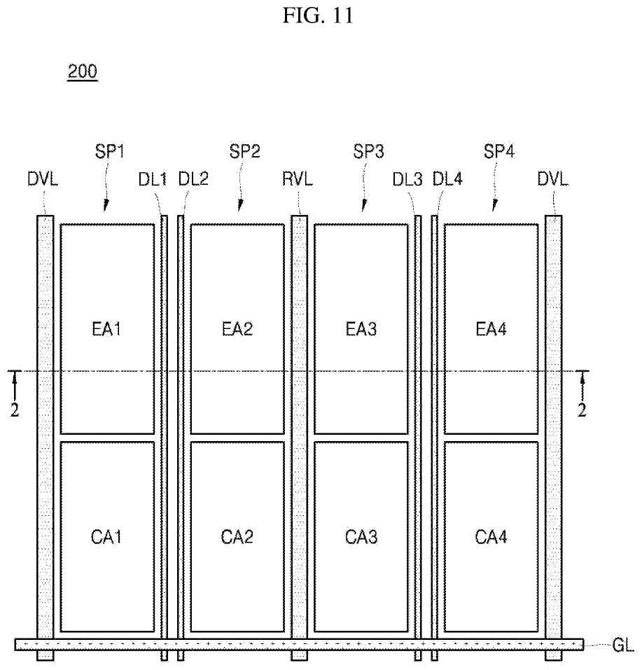

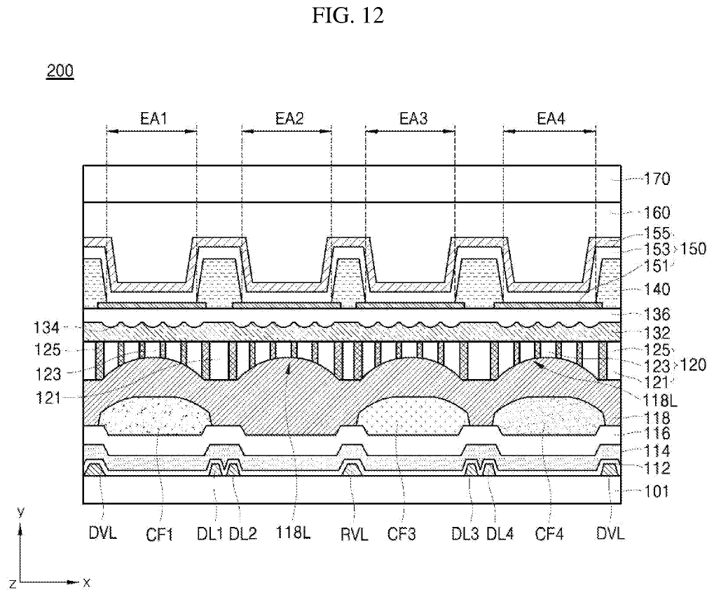

FIG. 11 is a plan view schematically showing the unit cell of the display device according to one example embodiment of the present disclosure.

Referring to FIG. 11, a display device 200 according to one example embodiment of the present disclosure may include the pixel including the first sub-pixel SP1, the second sub-pixel SP2 adjacent to the first sub-pixel SP1, the third sub-pixel SP3 adjacent to the second sub-pixel SP2, and a fourth sub-pixel SP4 adjacent to the third sub-pixel SP3. In the display device 200 according to one example embodiment of the present disclosure, the same pixels may be repeatedly disposed.

The first sub-pixel SP1 may include a first emission area EAl and a first circuit area CA1 for driving the first emission area. The second sub-pixel SP2 may include a second emission area EA2 and a second circuit area CA2 for driving the second emission area. The third sub-pixel SP3 may include a third emission area EA3 and a third circuit area CA3 for driving the third emission area. The fourth sub-pixel SP4 may include a fourth emission area EA4 and a fourth circuit area CA4 for driving the fourth emission area.

A light emitting element may be disposed in the first to fourth emission areas EA1, EA2, EA3, and EA4, and a thin film transistor and a capacitor may be disposed in the first to fourth circuit areas CA1, CA2, CA3, and CA4. For example, the light emitting element may emit white light.

For example, the first sub-pixel SP1 may be a red sub-pixel, the second sub-pixel SP2 may be a white sub-pixel, the third sub-pixel SP3 may be a blue sub-pixel, and the fourth sub-pixel SP4 may be a green sub-pixel.

The display device 200 according to one example embodiment of the present disclosure may include first to fourth data lines DL1, DL2, DL3, and DL4 to which data voltages are supplied by the data driver, the driving voltage line DVL to which the driving voltage is supplied, the reference voltage line RVL to which the reference voltage is supplied, and the gate line GL which intersects the first to fourth data lines DL1, DL2, DL3, and DL4 and to which the gate voltage is supplied by the gate driver. The driving voltage line DVL and the reference voltage line RVL may also intersect the gate line GL.

For example, the first to fourth data lines DL1, DL2, DL3, and DL4, the driving voltage line DVL, and the reference voltage line RVL may extend in the Y-axis direction, and the gate line GL may extend in the X-axis direction.

For example, the first sub-pixel SP1 may be disposed between the driving voltage line DVL and the first data line DL1, and the second sub-pixel SP2 may be disposed between the second data line DL2 and the reference voltage line RVL. For example, the third sub-pixel SP3 may be disposed between the reference voltage line RVL and the third data line DL3, and the fourth sub-pixel SP4 may be disposed between the fourth data line DLA and the driving voltage line DVL.

FIG. 12 is an example of a cross-sectional view along line 12-12 in FIG. 11.

Referring to FIG. 12, the driving voltage line DVL, the first data line DL1, the second data line DL2, the reference voltage line RVL, the third data line DL3, and the fourth data line DLA may be disposed to be spaced apart from each other on the substrate 101.

The buffer layer 112 may cover the driving voltage line DVL, the first data line DLI, the second data line DL2, the reference voltage line RVL, the third data line DL3, and the fourth data line DLA and may be disposed on the substrate 101.

The interlayer insulating layer 114 may be disposed on the buffer layer 112. In addition, the passivation layer 116 may be disposed on the interlayer insulating layer 114.

The first color filter CF1, the third color filter CF3, and the fourth color filter CF4 may be disposed on the passivation layer 116. The first color filter CF1 may be disposed in the first emission area EA1. The third color filter CF3 may be disposed in the third emission area EA3. The fourth color filter CF4 may be disposed in the fourth emission area EA4. The color filter may not be disposed in the second emission area EA2. For example, the first color filter CF1 may be a red color filter, the third color filter CF3 may be a blue color filter, and the fourth color filter CF4 may be a green color filter.

The first overcoat layer 118 may cover the first color filter CF1, the third color filter CF3, and the fourth color filter CF4 and may be disposed on the passivation layer 116. The first overcoat layer 118 may have convex-shaped lenses 118L disposed in the first, second, third, and fourth emission areas EA1, EA2, EA3, and EA4. The lenses 118L may be disposed on the first, third, and fourth color filters CF1, CF3, and CF4. The lenses 118L may be formed on the upper surface of the first overcoat layer 118 to overlap the first, third, and fourth color filters CF1, CF3, and CF4. The thickness of the first overcoat layer 118 of the second emission area EA2 may be greater than the thickness of the first overcoat layer 118 of the first, third, and fourth emission areas EA1, EA3, and EA4. The lenses 118L may be a portion of the first overcoat layer 118. In one example embodiment, the lenses 118L may be formed separately from the first overcoat layer 118 on the upper surface of the first overcoat layer 118.

With respect to a cross section of the lens 118L along a direction in which the gate line GL extends, an aspect ratio of the lens 118L may be in the range of 0.2 or more and 1.5 or less. The aspect ratio of the lens 118L may be in the range of 0.2 or more and 1.0 or less. The aspect ratio of the lens 118L may be defined as a ratio of the height of the lens to the size of the bottom surface of the lens.

The light control layer 120 may be disposed on the first overcoat layer 118. The light control layer 120 may include a plurality of micro pillars 123 disposed on each lens 118L, a light-absorbing mold 125 surrounding side surfaces of the plurality of micro pillars 123, and an insulating layer 121 surrounding side surfaces of the light-absorbing mold 125. The insulating layer 121 may be disposed on the remaining area of the upper surface of the first overcoat layer 118 excluding an area in which the plurality of micro pillars 123 and the light-absorbing mold 125 are disposed. The plurality of micro pillars 123 may be disposed in the first to fourth emission areas EA1, EA2, EA3, and EA4.

In one example embodiment, the light-absorbing mold 125 instead of the insulating layer 121 may be disposed.

The lower surfaces of the plurality of micro pillars 123 may be in contact with the lens 118L, and the upper surfaces of the plurality of micro pillars 123 may be flat.

The lower surface of the light-absorbing mold 125 may be in contact with the lens 118L, and the upper surface of the light-absorbing mold 125 may be flat. In one example embodiment, the upper surface of the light-absorbing mold 125 may be convex or concave.

The second refractive indexes of the plurality of micro pillars 123 may be higher than the first refractive index of the lens 118L.

The second overcoat layer 132 including the plurality of micro lenses 134 having a concave shape on the upper surface thereof may be disposed on the light control layer 120. The plurality of micro lenses 134 may be disposed in the first to fourth emission areas EA1, EA2, EA3, and EA4.

The third refractive index of the second overcoat layer 132 may be lower than the second refractive indexes of the plurality of micro pillars 123.

The third overcoat layer 136 may be disposed on the second overcoat layer 132. The third overcoat layer 136 may cover the plurality of micro lenses 134 of the second overcoat layer 132 and have a flat upper surface. The fourth refractive index of the third overcoat layer 136 may be higher than the third refractive index of the second overcoat layer 132.

The plurality of micro lenses 134 may be disposed to correspond one-to-one to the plurality of micro pillars 123. The diameter or size of each of the plurality of micro pillars 123 may be smaller than the diameter or size of each of the plurality of micro lenses 134.

The light emitting elements 150 may be disposed on the third overcoat layer 136. The first electrodes 151 spaced apart from each other may be disposed on the third overcoat layer 136. One first electrode 151 may be disposed in each sub-pixel.

The bank layer 140 may be disposed on the third overcoat layer 136. The bank layer 140 may cover edge portions of the first electrodes 151. The first to third emission areas EA1, EA2, and EA3 may be defined by portions of the first electrodes 151 not covered or obscured by the bank layer 140.

The organic light emitting layer 153 may be disposed on the first electrodes 151. The organic light emitting layer 153 may also be disposed on the bank layer 140.

The second electrode 155 may be disposed on the organic light emitting layer 153. The second electrode 155 may include a reflective conductive material.

The encapsulation layer 160 may be disposed on the second electrode 155, and the protective layer 170 may be disposed on the encapsulation layer 160.

According to one example embodiment of the present disclosure, it is possible to increase the light extraction efficiency of the display device 200 by arranging the micro lenses under the light emitting element.

In addition, the micro channels capable of blocking optical crosstalk can be formed by arranging the black light-absorbing mold for absorbing light between the micro pillars corresponding one-to-one under the micro lenses. Therefore, it is possible to increase the contrast ratio and resolution of the display device 200.

In addition, it is possible to increase the luminance viewing angle of the display device 200 by arranging the lens having a low refractive index under the micro pillars.

Various examples and aspects of the present disclosure are described below. These are provided as examples, and do not limit the scope of the present disclosure.

A display device according to one or more example embodiments of the present disclosure includes an emission area, a circuit area for driving the emission area, a first overcoat layer having a convex-shaped lens disposed in the emission area, a plurality of micro pillars disposed on the convex-shaped lens, a light-absorbing mold surrounding side surfaces of the plurality of micro pillars and disposed on the first overcoat layer, a second overcoat layer including a plurality of micro lenses corresponding to the plurality of micro pillars, a third overcoat layer disposed on the second overcoat layer and having a flat upper surface, and a light emitting element disposed on the third overcoat layer. Each of the plurality of micro lenses may have a concave shape.

According to some example embodiments, each of the plurality of micro pillars may correspond to a respective one of the plurality of micro lenses, establishing a one-to-one relationship between the plurality of micro pillars and the plurality of micro lenses.

According to some example embodiments, the light-absorbing mold may be disposed to correspond to a convex portion around the plurality of micro lenses.

According to some example embodiments, a refractive index of the convex-shaped lens may be lower than a refractive index of each of the plurality of micro pillars.

According to some example embodiments, a refractive index of each of the plurality of micro pillars may be higher than a refractive index of the second overcoat layer.

According to some example embodiments, a refractive index of the second overcoat layer may be lower than a refractive index of the third overcoat layer.

According to some example embodiments, a diameter or size of each of the plurality of micro pillars may be smaller than a diameter or size of each of the plurality of micro lenses.

According to some example embodiments, a width of the light-absorbing mold disposed outside the emission area may be greater than a width of the light-absorbing mold disposed in the emission area.

According to some example embodiments, the display device may further include a gate line disposed under the first overcoat layer, in which an aspect ratio of the convex-shaped lens may be in a range of 0.2 or more and 1.5 or less with respect to a cross section of the convex-shaped lens in a direction in which a gate line extends.

According to some example embodiments, lower surfaces of the plurality of micro pillars may be in contact with the convex-shaped lens, and upper surfaces of the plurality of micro pillars may be flat.

According to some example embodiments, the plurality of micro pillars may be located between the convex-shaped lens of the first overcoat layer and the second overcoat layer.

According to some example embodiments, the light-absorbing mold may extend to the circuit area and may be disposed on an entirety of the circuit area.

According to some example embodiments, the light emitting element may include a first electrode disposed on the third overcoat layer, an emission layer disposed on the first electrode, and a second electrode disposed on the emission layer, in which the first electrode may be connected to a thin film transistor by passing through the third overcoat layer, the second overcoat layer, the light-absorbing mold, and the first overcoat layer.

According to some example embodiments, the display device may further include a color filter disposed under the convex-shaped lens.

A display device according to one or more example embodiments of the present disclosure includes an emission area, a circuit area, a first overcoat layer having a convex-shaped lens disposed in the emission area, a light control layer disposed on the first overcoat layer, a second overcoat layer disposed on the light control layer and including a plurality of micro lenses, a third overcoat layer disposed on the second overcoat layer and having a flat upper surface, and a light emitting element disposed on the third overcoat layer. The plurality of micro lenses may overlap the convex-shaped lens, and each of the plurality of micro lenses may have a concave shape at an upper surface of the second overcoat layer. Here, the light control layer includes a plurality of transmissive parts, and a non-transmissive part around the plurality of transmissive parts. Each of the plurality of transmissive parts may correspond to a respective one of the plurality of micro lenses, establishing a one-to-one relationship between the plurality of transmissive parts and the plurality of micro lenses.

According to some example embodiments, a refractive index of the convex-shaped lens may be lower than a refractive index of each of the plurality of transmissive parts.

According to some example embodiments, a refractive index of each of the plurality of transmissive parts may be higher than a refractive index of the second overcoat layer.

According to some example embodiments, a refractive index of the second overcoat layer may be lower than a refractive index of the third overcoat layer.

According to some example embodiments, a diameter or size of each of the plurality of transmissive parts may be smaller than a diameter or size of each of the plurality of micro lenses.

According to some example embodiments, the display device may further include a gate line disposed under the first overcoat layer, and an aspect ratio of the convex-shaped lens may be in a range of 0.2 or more and 1.5 or less with respect to a cross section of the convex-shaped lens in a direction in which a gate line extends.

According to some example embodiments, lower surfaces of the plurality of transmissive parts may be in contact with the convex-shaped lens, and upper surfaces of the plurality of transmissive parts may be flat.

According to some example embodiments, the non-transmissive part may extend to the circuit area and may be disposed on an entirety of the circuit area.

According to some example embodiments, the light emitting element may include a first electrode disposed on the third overcoat layer, an emission layer disposed on the first electrode, and a second electrode disposed on the emission layer, in which the first electrode may be connected to a thin film transistor of the circuit area by passing through the third overcoat layer, the second overcoat layer, the non-transmissive part, and the first overcoat layer.

According to some example embodiments, the display device may further include a color filter disposed under the convex-shaped lens.

According to some example embodiments, the display device may further include an insulating layer surrounding the non-transmissive part. The insulating layer may be disposed on an area of an upper surface of the first overcoat layer, excluding an area on which the plurality of transmissive parts and the non-transmissive part are disposed.

According to one or more example embodiments of the present disclosure, it is possible to increase the light extraction efficiency of the display device by arranging the micro lenses under the light emitting element. Therefore, it is possible to reduce the consumed power of the display device.

In addition, according to one or more example embodiments of the present disclosure, the micro channels capable of blocking optical crosstalk can be formed by arranging the light-absorbing mold for absorbing light between the micro lenses and the micro pillars corresponding one-to-one thereto. Therefore, it is possible to increase the contrast ratio and resolution.

In addition, according to one or more example embodiments of the present disclosure, it is possible to increase the luminance viewing angle of the display device by arranging the convex-shaped lens having the low refractive index under the micro channels.

The effects of the present disclosure are not limited to the above-described effects, and other effects that are not mentioned will be able to be clearly understood by those skilled in the art from the present disclosure.

Although the example embodiments of the present disclosure have been described in detail with reference to the accompanying drawings, the present disclosure is not necessarily limited to these example embodiments, and various modifications may be carried out without departing from the technical spirit of the present disclosure. Therefore, the example embodiments disclosed in the specification are not intended to limit the technical features of the present disclosure, but for illustrative purposes, and the scope of the technical features of the present disclosure is not limited by these example embodiments. The scope of protection of the present disclosure should be construed based on the following claims, and all technical features within the scope of equivalents thereof should be construed as being included within the scope of the present disclosure.

What is claimed is:

1. A display device, comprising:
an emission area and a circuit area for driving the emission area;
a first overcoat layer having a convex-shaped lens disposed in the emission area;
a plurality of micro pillars disposed on the convex-shaped lens;
a light-absorbing mold surrounding side surfaces of the plurality of micro pillars and disposed on the first overcoat layer;
a second overcoat layer including a plurality of micro lenses corresponding to the plurality of micro pillars, wherein each of the plurality of micro lenses has a concave shape;
a third overcoat layer disposed on the second overcoat layer and having a flat upper surface; and
a light emitting element disposed on the third overcoat layer.

2. The display device of claim 1, wherein each of the plurality of micro pillars corresponds to a respective one of the plurality of micro lenses, establishing a one-to-one relationship between the plurality of micro pillars and the plurality of micro lenses.

3. The display device of claim 1, wherein the light-absorbing mold is disposed to correspond to a convex portion around the plurality of micro lenses.

4. The display device of claim 1, wherein a refractive index of the convex-shaped lens is lower than a refractive index of each of the plurality of micro pillars.

5. The display device of claim 1, wherein a refractive index of each of the plurality of micro pillars is higher than a refractive index of the second overcoat layer.

6. The display device of claim 1, wherein a refractive index of the second overcoat layer is lower than a refractive index of the third overcoat layer.

7. The display device of claim 1, wherein a diameter or size of each of the plurality of micro pillars is smaller than a diameter or size of each of the plurality of micro lenses.

8. The display device of claim 1, wherein a width of the light-absorbing mold disposed outside the emission area is greater than a width of the light-absorbing mold disposed in the emission area.

9. The display device of claim 1, further comprising a gate line disposed under the first overcoat layer, wherein an aspect ratio of the convex-shaped lens is in a range of 0.2 or more and 1.5 or less with respect to a cross section of the convex-shaped lens in a direction in which the gate line extends.

10. The display device of claim 1, wherein lower surfaces of the plurality of micro pillars are in contact with the convex-shaped lens, and upper surfaces of the plurality of micro pillars are flat.

11. The display device of claim 1, wherein the plurality of micro pillars are located between the convex-shaped lens of the first overcoat layer and the second overcoat layer.

12. The display device of claim 1, wherein the light-absorbing mold extends to the circuit area and is disposed on an entirety of the circuit area.

13. The display device of claim 1, wherein the light emitting element includes: a first electrode disposed on the third overcoat layer; an emission layer disposed on the first electrode; and a second electrode disposed on the emission layer, and
wherein the first electrode is connected to a thin film transistor of the circuit area by passing through the third overcoat layer, the second overcoat layer, the light-absorbing mold, and the first overcoat layer.

14. The display device of claim 1, further comprising a color filter disposed under the convex-shaped lens.

15. A display device, comprising:
an emission area and a circuit area;
a first overcoat layer having a convex-shaped lens disposed in the emission area;
a light control layer disposed on the first overcoat layer;
a second overcoat layer disposed on the light control layer and including a plurality of micro lenses, wherein the plurality of micro lenses overlap the convex-shaped lens, and wherein each of the plurality of micro lenses has a concave shape at an upper surface of the second overcoat layer;
a third overcoat layer disposed on the second overcoat layer and having a flat upper surface; and
a light emitting element disposed on the third overcoat layer,
wherein the light control layer includes:
a plurality of transmissive parts disposed on the convex-shaped lens, wherein each of the plurality of transmissive parts corresponds to a respective one of the plurality of micro lenses, establishing a one-to-one relationship between the plurality of transmissive parts and the plurality of micro lenses; and
a non-transmissive part around the plurality of transmissive parts.

16. The display device of claim 15, wherein a refractive index of the convex-shaped lens is lower than a refractive index of each of the plurality of transmissive parts.

17. The display device of claim 15, wherein a refractive index of each of the plurality of transmissive parts is higher than a refractive index of the second overcoat layer.

18. The display device of claim 15, wherein a refractive index of the second overcoat layer is lower than a refractive index of the third overcoat layer.

19. The display device of claim 15, wherein a diameter or size of each of the plurality of transmissive parts is smaller than a diameter or size of each of the plurality of micro lenses. 20 The display device of claim 15, further comprising a gate line disposed under the first overcoat layer, wherein an aspect ratio of the convex-shaped lens is in a range of 0.2 or more and 1.5 or less with respect to a cross section of the convex-shaped lens in a direction in which the gate line extends.

21. The display device of claim 15, wherein lower surfaces of the plurality of transmissive parts are in contact with the convex-shaped lens, and upper surfaces of the plurality of transmissive parts are flat.

22. The display device of claim 15, wherein the non-transmissive part extends to the circuit area and is disposed on an entirety of the circuit area.

23. The display device of claim 15, wherein the light emitting element includes: a first electrode disposed on the third overcoat layer; an emission layer disposed on the first electrode;
and a second electrode disposed on the emission layer, and wherein the first electrode is connected to a thin film transistor of the circuit area by passing through the third overcoat layer, the second overcoat layer, the non-transmissive part, and the first overcoat layer.

24. The display device of claim 15, further comprising a color filter disposed under the convex-shaped lens.

25. The display device of claim 15, further comprising an insulating layer surrounding the non-transmissive part,
wherein the insulating layer is disposed on an area of an upper surface of the first overcoat layer, excluding an area on which the plurality of transmissive parts and the non-transmissive part are disposed.
